(19) United States
(12) Patent Application Publication
(10) Pub. No.: US 2024/0178151 A1
(43) Pub. Date: May 30, 2024

(54) OVERLYING FIDUCIAL DESIGN FOR GLASS PLACEMENT ACCURACY IMPROVEMENT

(71) Applicant: Intel Corporation, Santa Clara, CA (US)

(72) Inventors: Minglu LIU, Chandler, AZ (US); Alexander AGUINAGA, Phoenix, AZ (US); Gang DUAN, Chandler, AZ (US); Jung Kyu HAN, Chandler, AZ (US); Yosuke KANAOKA, Chandler, AZ (US); Yi LI, Chandler, AZ (US); Robin MCREE, Chandler, AZ (US); Hong Seung YEON, Chandler, AZ (US)

(21) Appl. No.: 18/071,901

(22) Filed: Nov. 30, 2022

(51) Int. Cl. H01L 23/544; H01L 23/15; H01L 23/498

(52) U.S. Cl. CPC H01L 23/544; H01L 23/15; H01L 23/49816

(57) ABSTRACT

Embodiments disclosed herein include a package architecture. In an embodiment, the package architecture comprises a first substrate with a first fiducial mark on a surface of the first substrate. In an embodiment, the package architecture further comprises a second substrate over the first substrate, where the second substrate comprises glass and a second fiducial mark on the second substrate, and where a footprint of the second fiducial mark at least partially overlaps a footprint of the first fiducial mark.

### TECHNICAL FIELD

Embodiments of the present disclosure relate to electronic packages, and more particularly to packaging architectures that include a glass substrate with a first fiducial that is provided over a second fiducial on an underlying substrate.

### BACKGROUND

In existing chip/device attachment processes, alignment is done by fiducial mark recognition on two components separately. In one instance, two different cameras are used, one for each fiducial mark. In other instances the same camera is used for both fiducial marks, but different field of views (FOVs) are needed. In yet another instance, different locations are imaged within the same FOV. All three options can induce misalignment, due to for example, camera-to-camera offset between two cameras, camera motion when using a single camera to capture two FOVs, and fiducial image distortion due to the fiducials not being in the center of the FOV.

That is, a first fiducial mark on a first substrate is imaged, and a second fiducial mark on a second, overlying, substrate is imaged. This offset nature of the first and second fiducial marks is necessary when the second substrate is not transparent. (e.g., when the second substrate is an organic dielectric, such as a buildup film or the like). However, in advanced processing, interposers, glass couplers, or other devices are increasingly being formed from transparent materials, such as glass. The use of glass enables alternative alignment processes, which may provide more accurate alignment between substrates.

### BRIEF DESCRIPTION OF THE DRAWINGS

FIG. 1 is a plan view illustration of a first substrate with a plurality of second substrates with offset fiducial marks.

FIG. 2 is a plan view illustration of a first substrate with a plurality of transparent second substrates with overlapping fiducial marks, in accordance with an embodiment.

FIG. 3 is a cross-sectional illustration of an electronic package with a first substrate with a first fiducial mark and a second substrate with a second fiducial mark, in accordance with an embodiment.

FIG. 4 is a cross-sectional illustration of an electronic package with a first substrate with a cavity and a first fiducial mark, and a second substrate with a second fiducial mark within the cavity, in accordance with an embodiment.

FIG. 5A is a cross-sectional illustration of an electronic package with a second substrate being aligned over a first substrate, in accordance with an embodiment.

FIG. 5B is a cross-sectional illustration of the electronic package of FIG. 5A after the first substrate is brought into contact with the second substrate, in accordance with an embodiment.

FIG. 6A is a plan view illustration of an electronic package with overlapping fiducial marks that are both circular, in accordance with an embodiment.

FIG. 6B is a cross-sectional illustration of the electronic package in FIG. 6A, in accordance with an embodiment.

FIG. 7A is a plan view illustration of an electronic package with overlapping fiducial marks where the first fiducial mark is a circular ring, in accordance with an embodiment.

FIG. 7B is a cross-sectional illustration of the electronic package in FIG. 7A, in accordance with an embodiment.

FIG. 8A is a plan view illustration of an electronic package with overlapping fiducial marks where the second fiducial mark is a circular ring, in accordance with an embodiment.

FIG. 8B is a cross-sectional illustration of the electronic package in FIG. 8A, in accordance with an embodiment.

FIG. 9A is a plan view illustration of an electronic package with overlapping fiducial marks where both fiducial marks are circular rings, in accordance with an embodiment.

FIG. 9B is a cross-sectional illustration of the electronic package in FIG. 9A, in accordance with an embodiment.

FIG. 10A is a plan view illustration of an electronic package with overlapping fiducial marks where both fiducial marks are cross-shaped, in accordance with an embodiment.

FIG. 10B is a cross-sectional illustration of the electronic package in FIG. 10A, in accordance with an embodiment.

FIG. 11A is a plan view illustration of an electronic package with overlapping fiducial marks where both fiducial marks are rectangular shaped, in accordance with an embodiment.

FIG. 11B is a cross-sectional illustration of the electronic package in FIG. 11A, in accordance with an embodiment.

FIG. 12 is a cross-sectional illustration of an electronic system with a pair of substrates that are aligned with each other using overlapping fiducial marks, in accordance with an embodiment.

FIG. 13 is a schematic of a computing device built in accordance with an embodiment.

### EMBODIMENTS OF THE PRESENT DISCLOSURE

Described herein are packaging architectures that include a glass component with a first fiducial that is provided over a second fiducial on an underlying substrate, in accordance with various embodiments. In the following description, various aspects of the illustrative implementations will be described using terms commonly employed by those skilled in the art to convey the substance of their work to others skilled in the art.

However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, when devices are aligned on a panel or carrier, the device and the panel both have alignment marks. Alignment marks may also be referred to herein as fiducial marks, or simply as fiducials. In existing architectures, the device is typically opaque. For example, the device may be a die, a chip, an interposer, a coupler, or the like. As such, it is not possible to “see” through the substrate using conventional imaging (e.g., optical cameras). As such, the fiducial marks on the panel need to be outside the footprint of the substrate.

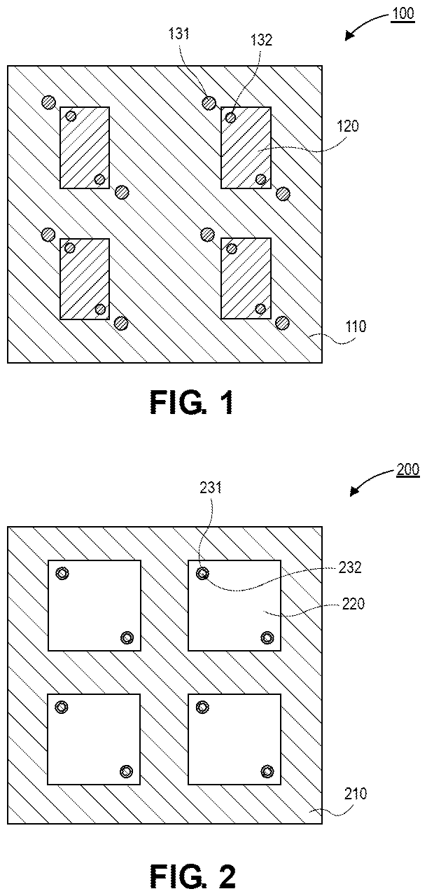

An example of such an architecture is shown in FIG. 1. As shown, a system 100 includes a panel 110 and a plurality of substrates 120 arranged over the panel 110. Each substrate 120 can be aligned using first fiducials 131 on the panel 110 and second fiducials 132 on the substrate 120. However, since the first fiducials 131 and the second fiducials 132 are offset from each other, imaging may result in alignment errors. For example, a pair of two cameras may be used, a single camera with different field of views (FOVs) can be used, or both fiducial marks may be captured in a single FOV. In the first two options, the movement or displacement between cameras can lead to errors in the imaging. In the third option, the fiducial marks are offset from a center of the FOV and can lead to distortions.

Due to the opaque nature of the substrates 120, it is difficult to enable improved alignment processing. However, as transparent substrates 120 become more common, new alignment solutions are possible. Transparent substrates 120 may include, for example, glass substrates 120. Glass substrates 120 are increasing being used for architectures such as interposers, bridges, optical routing and connectors, and the like. In the case of a glass substrate 120, the fiducial marks that were outside of the footprint of the substrate 120 can be moved into the footprint of the substrate. More particularly, a footprint of the first fiducials 131 may be at least partially overlapping a footprint of the second fiducials 132. As such, a single camera with a FOV that is centered on both fiducials 131 and 132 can be used to improve alignment accuracy.

An example of such an embodiment is shown in FIG. 2. FIG. 2 is a plan view illustration of a system 200 that includes a first substrate 210 and a plurality of second substrates 220. In an embodiment, the first substrate 210 may be a panel level substrate, a quarter-panel level substrate, or any other form factor. In some embodiments, the first substrate 210 may be a carrier used in the fabrication of electronic packages. That is, the first substrate 210 may be removed in subsequent processing operations, and may not be part of the final electronic package structure. In other embodiments, the first substrate 210 may be part of the final electronic package structure. For example, the first substrate may be diced into a plurality of package substrates for the final electronic package.

In an embodiment, a plurality of second substrates 220 are provided across the first substrate 210. In an embodiment, the second substrates 220 may comprise any type of structure, such as a chip, a die, an interposer, a coupler, or the like. The second substrates 220 may include an optically transparent material. As used herein, “optically transparent” may refer to being transparent to one or more electromagnetic wavelengths in the visible light spectrum. For example, the second substrates 220 may comprise glass in some embodiments. The glass may be any suitable glass material, such as borosilicate glass, fused silica glass, or the like. In the illustrated embodiment, a set of four second substrates 220 are shown. Though, it is to be appreciated that any number of second substrates 220 may be provided over the first substrate 210 in the system 200. In the illustrated embodiment, the second substrates 220 are substantially square. In other embodiments, the second substrates 220 may be rectangular or any other shape.

In an embodiment, the first substrate 210 may comprise a plurality of first fiducial marks 231. As shown, the first fiducial marks 231 are located below (and within a footprint of) the second substrates 220. Since the second substrates 220 are optically transparent, the first fiducial marks 231 can be seen through the second substrates 220. In some embodiments a pair of first fiducial marks 231 may be provided below each second substrate 220. For example, each second substrate 220 may have a pair of first fiducial marks 231 in opposite corners. The use of two or more first fiducial marks 231 allows for X-Y alignment as well as rotational alignment.

In an embodiment, the second substrates 220 may also include second fiducial marks 232. The second fiducial marks 232 may be provided at locations so that they at least partially overlap the first fiducial marks 231. As such, by imaging the overlap between the first fiducial marks 231 and the second fiducial marks 232, a proper alignment of the second substrates 220 with respect to the first substrate 210 can be obtained.

In the particular embodiment shown in FIG. 2, the alignment is a circle-in-circle alignment. That is, the first fiducial marks 231 are circles with a first diameter, and the second fiducial marks 232 are circles with a second (smaller) diameter. As such, centering the second fiducial marks 232 on the first fiducial marks 231 can provide the proper alignment. In an embodiment, a ratio of the diameter of the second fiducial marks 232 to the diameter of the first fiducial marks may be approximately 1:4 to approximately 3:4. For example, the first fiducial marks 131 may have a diameter between approximately 50 μm and approximately 500 μm, and the second fiducial marks 132 may have a diameter between approximately 25 μm and approximately 250 μm. As used herein, “approximately” may refer to a range of values within ten percent of the stated value. For example, approximately 100 μm may refer to a range between 90 μm and 110 μm.

Additionally, since the second fiducial marks 232 overlap the first fiducial marks 231, different materials can be used in order to provide contrast between the two fiducial marks 231 and 232. For example, the first fiducial marks 231 may comprise copper, and the second fiducial marks 232 may comprise aluminum. Though, it is to be appreciated that any material combination may be used. Additionally, the same material may be used for both fiducial marks 231 and 232 when other contrast features are present, as will be described in greater detail below.

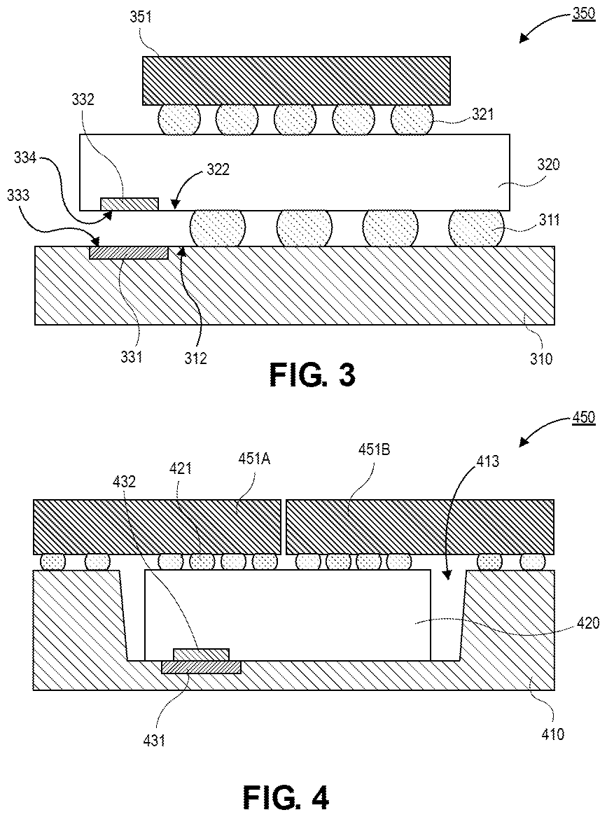

Referring now to FIG. 3, a cross-sectional illustration of an electronic package 350 is shown, in accordance with an embodiment. In an embodiment, the electronic package 350 comprises a first substrate 310 and an overlying second substrate 320. The first substrate 310 may be a package substrate. For example, the first substrate 310 may include organic dielectric layers, such as buildup film, or the like. The second substrate 320 may be an optically transparent substrate, such as glass or the like. In a particular embodiment, the second substrate 320 may be an interposer substrate. Conductive routing (not shown) may be provided in both the first substrate 310 and the second substrate 320. In some instances, optical routing (e.g., optical waveguides, couplers, etc.) may be included on the second substrate 320 as well. Interconnects 311, such as solder balls or the like, may be provided between the first substrate 310 and the second substrate 320.

In an embodiment, one or more dies 351 may be coupled to the second substrate 320. The one or more dies 351 may be compute dies, such as processors, graphics processors, systems on a chip (SoC), application specific integrated circuits (ASICs), or the like. The one or more dies 351 may also include memory dies in some instances. In an embodiment, the one or more dies 351 may be coupled to the second substrate 320 by interconnects 321. Interconnects 321 may include any first level interconnect (FLI) architecture.

In an embodiment, a first fiducial mark 331 may be provided on the first substrate 310. The first fiducial mark 331 may have a top surface 333 that is substantially coplanar with a top surface 312 of the first substrate 310. That is, the first fiducial mark 331 may be considered as being embedded in the first substrate 310. However, in other embodiments, the first fiducial mark 331 may extend up from the top surface 312 of the first substrate 310.

In an embodiment, a second fiducial mark 332 may be provided on the second substrate 320. The second fiducial mark 332 may be provided at least partially over the first fiducial mark 331. The second fiducial mark 332 may be embedded in the second substrate 320. For example, a bottom surface 334 of the second fiducial mark 332 may be substantially coplanar with a bottom surface 322 of the second substrate 320. However, in other embodiments, the second fiducial mark 332 may extend out past the bottom surface 322 of the second substrate 320.

In an embodiment, the first fiducial mark 331 and the second fiducial mark 332 can be imaged from above by a camera (not shown). In a properly aligned electronic package 350, the second fiducial mark 332 will be substantially centered on the first fiducial mark 331. Various different fiducial mark architectures may be used in the electronic package 350. For example, various fiducial mark architectures are provided in greater detail below. Additionally, as indicated by their different shadings, the first fiducial mark 331 may be a different material than the second fiducial mark 332. Due to the presence of interconnects 311, the second fiducial mark 332 may be spaced away from the first fiducial mark 331.

Referring now to FIG. 4, a cross-sectional illustration of an electronic package 450 is shown, in accordance with an embodiment. In an embodiment, the electronic package 450 may include a first substrate 410 and a second substrate 420. The first substrate 410 may be an organic dielectric material, such as a substrate comprising buildup film. In an embodiment, the first substrate 410 may comprise a cavity 413. The cavity 413 may have sidewalls that are vertical or sloped, depending on the method of forming the cavity 413. The cavity 413 may go into the top surface of the first substrate 410 and stop a depth less than a thickness of the first substrate 410.

In an embodiment, the second substrate 420 may be a bridge that is set into the cavity 413 of the first substrate 410. The second substrate 420 may comprise an optically transparent material, such as glass or the like. The second substrate 420 may be supported from below by the first substrate 410. In some instances the second substrate 420 directly contacts the first substrate 410. Though, intervening layers (e.g., redistribution layers, solder interconnect layers, etc.) may be present between the first substrate 410 and the second substrate 420 in some embodiments.

In an embodiment, the second substrate 420 is a bridge that functions to communicatively couple a first die 451A to a second die 451B. In that respect, the second substrate 420 may include high density conductive or optical routing (not shown). FLIs 421 may connect the first die 451A and the second die 451B to the second substrate 420. The first die 451A and the second die 451B may be compute dies such as processors, graphics processors, SoCs, ASICs, or the like. One or more of the dies 451A and 451B may also include memory dies in some instances.

In an embodiment, a first fiducial mark 431 may be provided on the first substrate 410. The first fiducial mark 431 may be provided at a bottom of the cavity 413. In the illustrated embodiment, the first fiducial mark 431 is fully embedded in the first substrate 410. In an embodiment, a second fiducial mark 432 may be provided on the second substrate 420. The second fiducial mark 432 may be provided at least partially over the first fiducial mark 431. The second fiducial mark 432 may be embedded in the second substrate 420. As illustrated in FIG. 4, the first fiducial mark 431 may be directly contacting the second fiducial mark 432. In other embodiments, the first fiducial mark 431 and the second fiducial mark 432 may be separated by one or more intervening layers or by an air gap.

In an embodiment, the first fiducial mark 431 and the second fiducial mark 432 can be imaged from above by a camera (not shown). In a properly aligned electronic package 450, the second fiducial mark 432 will be substantially centered on the first fiducial mark 431. Various different fiducial mark architectures may be used in the electronic package 450. For example, various fiducial mark architectures are provided in greater detail below. Additionally, as indicated by their different shadings, the first fiducial mark 431 may be a different material than the second fiducial mark 432.

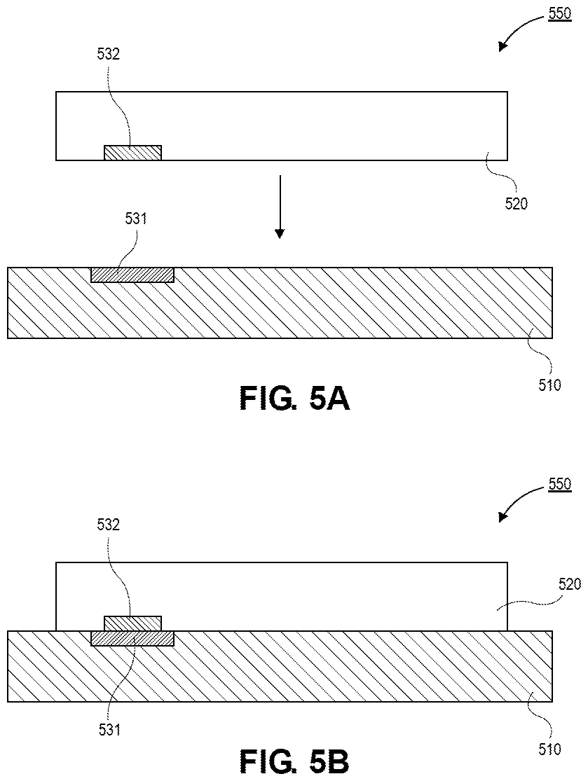

Referring now to FIGS. 5A and 5B, a process for aligning a first substrate 510 and a second substrate 520 is shown, in accordance with an embodiment. As shown in FIG. 5A, the second substrate 520 is provided in a spaced away position relative to the first substrate 510. The first substrate 510 may be a panel or the like. In some embodiments, the first substrate 510 is a carrier. In other embodiments, the first substrate 510 may be part of the final electronic package 550. The second substrate 520 may be an optically transparent material, such as glass. In an embodiment, the second substrate 520 may be an interposer, a bridge, or the like.

In an embodiment, the second substrate 520 may be moved (e.g., by a robot handling tool (not shown)) in the X-Y plane (i.e., left, right, into the plane of FIG. 5A, and out of the plane of FIG. 5A) in order to properly position the second substrate 520 over the first substrate 510. More particularly, a camera (not shown) that is above the second substrate 520 may have a FOV that includes the first fiducial marks 531 on the first substrate 510 and the second fiducial mark 532 on the second substrate 520. Further, while a single pair of fiducial marks 531 and 532 are shown in FIG. 5A, it is to be appreciated that multiple fiducial mark pairings can be used in order to provide X-Y alignment as well as rotational alignment. After the proper alignment is obtained, the robot handling tool moves the second substrate 520 towards the first substrate 510, as indicated by the downward pointing arrow.

Referring now to FIG. 5B, a cross-sectional illustration of the electronic package 550 after the first substrate 510 and the second substrate 520 are brought into contact with one another is shown, in accordance with an embodiment. In a particular embodiment, the first substrate 510 directly contacts the second substrate 520. Additionally, the first fiducial marks 531 directly contacts the second fiducial mark 532. In other embodiments, the first substrate 510 and the second substrate 520 may be spaced apart from each other by one or more intervening layers, by an air gap, or the like. After the second substrate 520 is secured to the first substrate 510, the electronic package 550 may be further processed, e.g., to form a structure similar to structures described in greater detail herein.

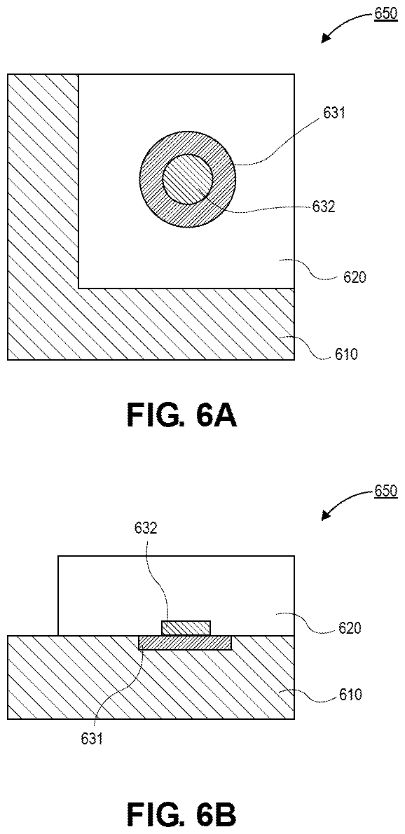

Referring now to FIGS. 6A and 6B, a plan view illustration (FIG. 6A) and a corresponding cross-sectional illustration (FIG. 6B) of a portion of an electronic package 650 are shown, in accordance with an embodiment. More particularly, FIGS. 6A and 6B illustrate the structure of the fiducial marks 631 and 632 in the first substrate 610 and the second substrate 620, respectively. As shown in FIG. 6A, the first fiducial mark 631 and the second fiducial mark 632 are circular. The first fiducial mark 631 has a diameter that is greater than a diameter of the second fiducial mark 632. As such, the outer perimeter of the first fiducial mark 631 is visible through the second substrate 620. Accordingly, the positioning of the edge of the second fiducial 632 mark relative to the edge of the first fiducial mark 631 can be imaged in order to determine when proper alignment is obtained. In order to improve the contrast between the first fiducial mark 631 and the second fiducial mark 632, the first fiducial mark 631 and the second fiducial mark 632 may be formed from different materials.

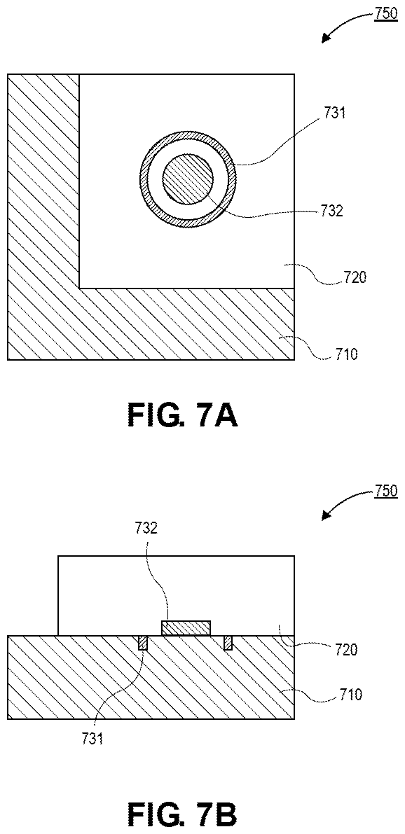

Referring now to FIGS. 7A and 7B, a plan view illustration (FIG. 7A) and a corresponding cross-sectional illustration (FIG. 7B) of a portion of an electronic package 750 are shown, in accordance with an embodiment. More particularly, FIGS. 7A and 7B illustrate the structure of the fiducial marks 731 and 732 in the first substrate 710 and the second substrate 720, respectively. As shown in FIG. 7A, the first fiducial mark 731 has a circular ring shape and the second fiducial mark 732 is circular. The first fiducial mark 731 has an outer diameter and an inner diameter that are both greater than a diameter of the second fiducial mark 732. As such, the outer and inner perimeters of the first fiducial mark 731 are visible through the second substrate 720. Accordingly, the positioning of the edge of the second fiducial mark 732 relative to an inner or outer edge of the first fiducial mark 731 can be imaged in order to determine when proper alignment is obtained. In the illustrated embodiment, the first fiducial mark 731 and the second fiducial mark 732 are formed from different materials. However, since a gap is provided between an inner surface of the first fiducial mark 731 and the outer surface of the second fiducial mark 732, the same material may be used for both fiducial marks 731 and 732.

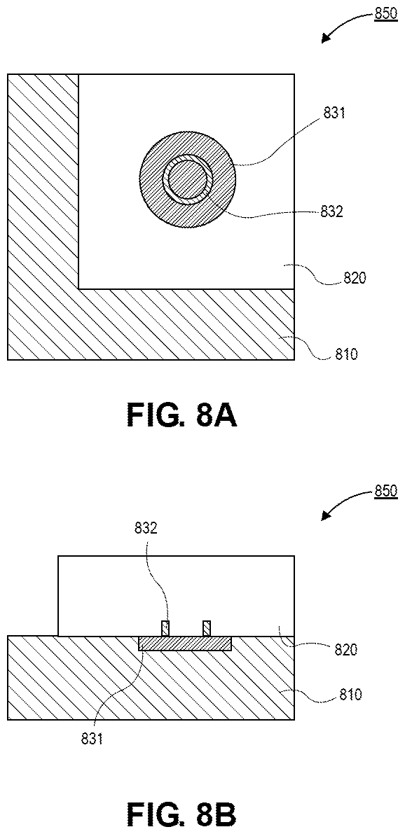

Referring now to FIGS. 8A and 8B, a plan view illustration (FIG. 8A) and a corresponding cross-sectional illustration (FIG. 8B) of a portion of an electronic package 850 are shown, in accordance with an embodiment. More particularly, FIGS. 8A and 8B illustrate the structure of the fiducial marks 831 and 832 in the first substrate 810 and the second substrate 820, respectively. As shown in FIG. 8A, the first fiducial mark 831 is circular and the second fiducial mark 832 is a circular ring. The first fiducial mark 831 has a diameter that is greater than an outer diameter of the second fiducial mark 832. As such, the outer perimeter of the first fiducial mark 831 is visible through the second substrate 820. Accordingly, the positioning of the edge of the second fiducial mark 832 relative to the edge of the first fiducial mark 831 can be imaged in order to determine when proper alignment is obtained. In order to improve the contrast between the first fiducial mark 831 and the second fiducial mark 832, the first fiducial mark 831 and the second fiducial mark 832 may be formed from different materials.

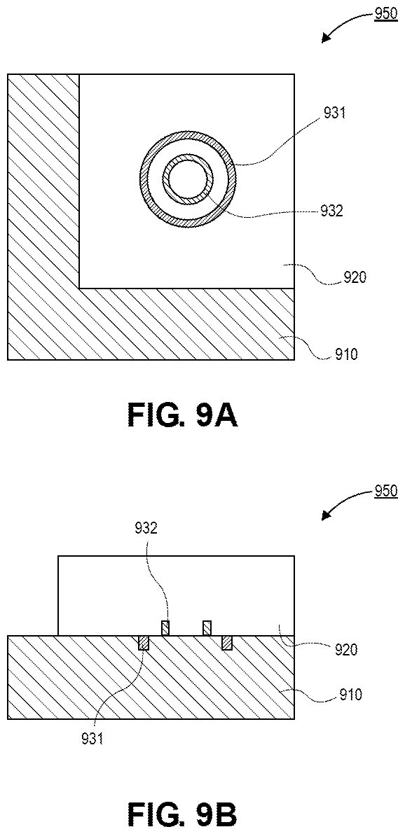

Referring now to FIGS. 9A and 9B, a plan view illustration (FIG. 9A) and a corresponding cross-sectional illustration (FIG. 9B) of a portion of an electronic package 950 are shown, in accordance with an embodiment. More particularly, FIGS. 9A and 9B illustrate the structure of the fiducial marks 931 and 932 in the first substrate 910 and the second substrate 920, respectively. As shown in FIG. 9A, the first fiducial mark 931 and the second fiducial mark 932 are both circular rings. The first fiducial mark 931 has an inner diameter that is greater than an outer diameter of the second fiducial mark 932. As such, the entirety of the first fiducial mark 931 is visible through the second substrate 920. Accordingly, the positioning of the outer edge of the second fiducial mark 932 relative to the inner or outer edge of the first fiducial mark 931 can be imaged in order to determine when proper alignment is obtained. In order to improve the contrast between the first fiducial mark 931 and the second fiducial mark 932, the first fiducial mark 931 and the second fiducial mark 932 may be formed from different materials. Though, since the edges of the first fiducial mark 931 and the second fiducial mark 932 are spaced apart by a gap, the same material may be used for the first fiducial mark 931 and the second fiducial mark 932 in some embodiments.

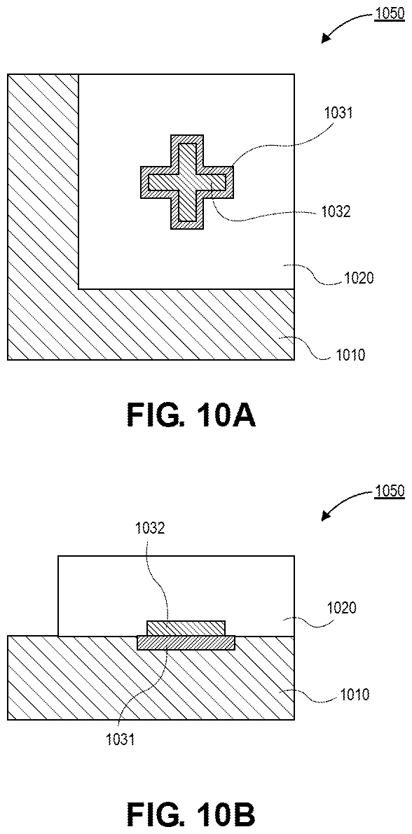

Referring now to FIGS. 10A and 10B, a plan view illustration (FIG. 10A) and a corresponding cross-sectional illustration (FIG. 10B) of a portion of an electronic package 1050 are shown, in accordance with an embodiment. More particularly, FIGS. 10A and 10B illustrate the structure of the fiducial marks 1031 and 1032 in the first substrate 1010 and the second substrate 1020, respectively. As shown in FIG. 10A, the first fiducial mark 1031 and the second fiducial mark 1032 are cross-shaped. The first fiducial mark 1031 has a larger perimeter than a perimeter of the second fiducial mark 1032. As such, the outer perimeter of the first fiducial mark 1031 is visible through the second substrate 1020. Accordingly, the positioning of the edge of the second fiducial mark 1032 relative to the edge of the first fiducial mark 1031 can be imaged in order to determine when proper alignment is obtained. In order to improve the contrast between the first fiducial mark 1031 and the second fiducial mark 1032, the first fiducial mark 1031 and the second fiducial mark 1032 may be formed from different materials.

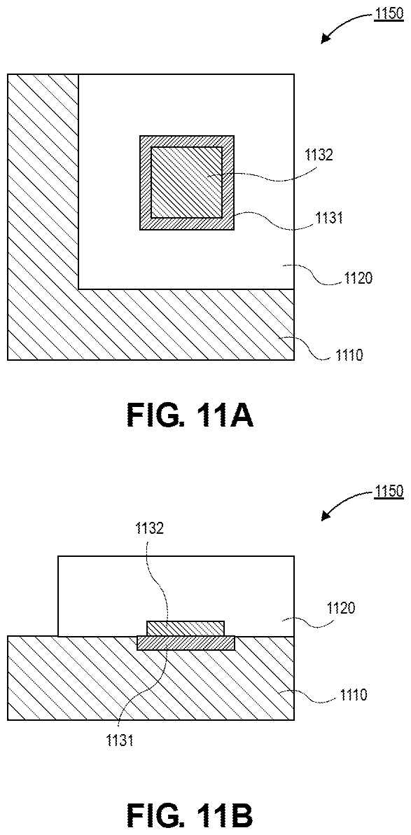

Referring now to FIGS. 11A and 11B, a plan view illustration (FIG. 11A) and a corresponding cross-sectional illustration (FIG. 11B) of a portion of an electronic package 1150 are shown, in accordance with an embodiment. More particularly, FIGS. 11A and 11B illustrate the structure of the fiducial marks 1131 and 1132 in the first substrate 1110 and the second substrate 1120, respectively. As shown in FIG. 11A, the first fiducial mark 1131 and the second fiducial mark 1132 are rectangular. The first fiducial mark 1131 has a width that is greater than a width of the second fiducial mark 1132. As such, the outer perimeter of the first fiducial mark 1131 is visible through the second substrate 1120. Accordingly, the positioning of the edge of the second fiducial mark 1132 relative to the edge of the first fiducial mark 1131 can be imaged in order to determine when proper alignment is obtained. In order to improve the contrast between the first fiducial mark 1131 and the second fiducial mark 1132, the first fiducial mark 1131 and the second fiducial mark 1132 may be formed from different materials.

While various different architectures for the fiducial marks are shown in the Figures above, it is to be appreciated that the first fiducial mark and the second fiducial mark may take any shape or structure that can be used to align two substrates. For example, a cross-in-box configuration may be used in some embodiments.

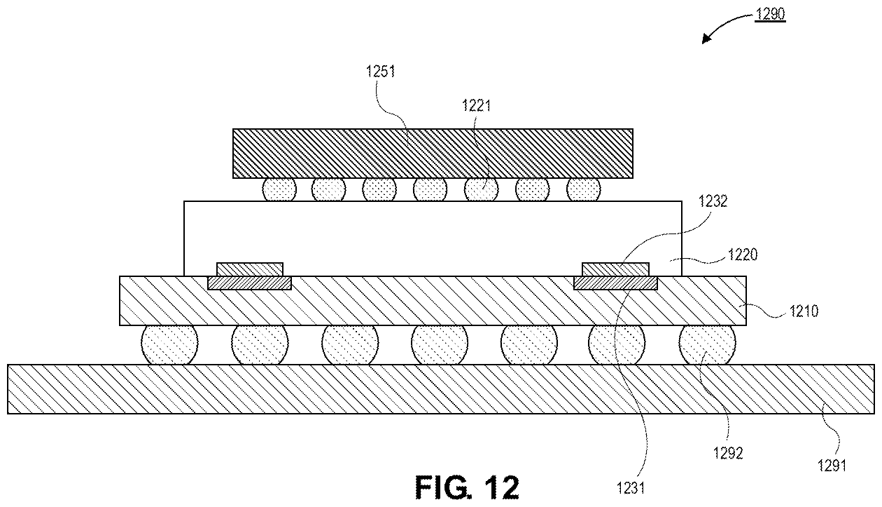

Referring now to FIG. 12, a cross-sectional illustration of an electronic system 1290 is shown, in accordance with an embodiment. In an embodiment, the electronic system 1290 may include a board 1291, such as a printed circuit board (PCB). In an embodiment, the board 1291 may be coupled to a first substrate 1210 by interconnects 1292, such as solder balls or the like. In an embodiment, a second substrate 1220 may be coupled to the first substrate 1210. In the illustrated embodiment, the second substrate 1220 is directly on the first substrate 1210. Though in some instances, an intervening layer and/or solder interconnects may be provided between the first substrate 1210 and the second substrate 1220. In an embodiment, the second substrate 1220 may be an interposer or the like. In a particular embodiment, the second substrate 1220 is a material that is optically transparent, such as glass. In an embodiment, one or more dies 1251 may be coupled to the second substrate 1220 by FLIs 1221. The die 1251 may include a compute die, a memory die, or any other type of die.

In an embodiment, the second substrate 1220 may be aligned to the first substrate 1210 using first fiducial marks 1231 and second fiducial marks 1232. The first fiducial marks 1231 may be at least partially overlapped by the second fiducial marks 1232. Since the second substrate 1220 is optically transparent, the orientation of the first fiducial marks 1231 with respect to the second fiducial marks 1232 can be determined in order to enable proper alignment. In an embodiment, the first fiducial marks 1231 and the second fiducial marks 1232 may include any fiducial mark architecture, such as those described in greater detail herein.

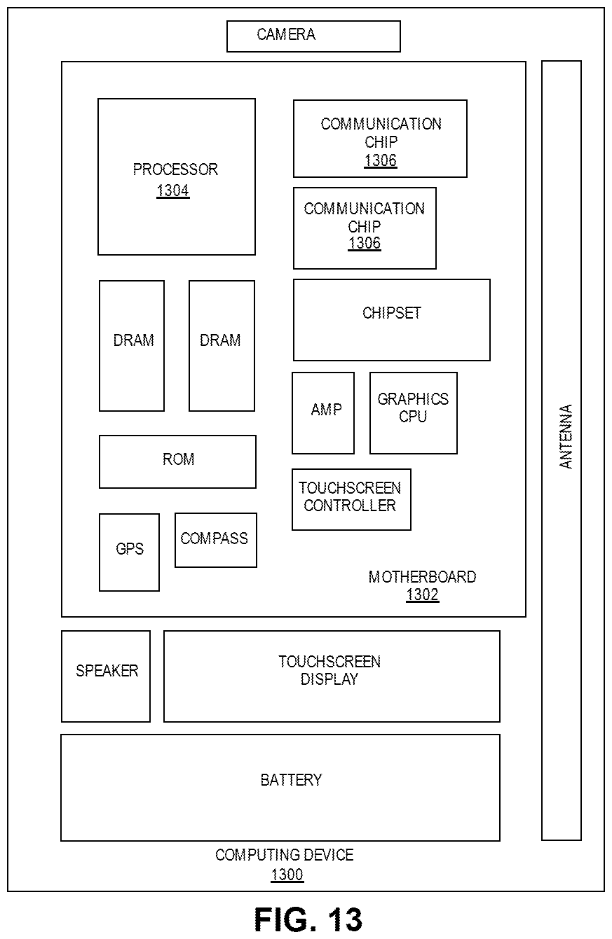

FIG. 13 illustrates a computing device 1300 in accordance with one implementation of the invention. The computing device 1300 houses a board 1302. The board 1302 may include a number of components, including but not limited to a processor 1304 and at least one communication chip 1306. The processor 1304 is physically and electrically coupled to the board 1302. In some implementations the at least one communication chip 1306 is also physically and electrically coupled to the board 1302. In further implementations, the communication chip 1306 is part of the processor 1304.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1306 enables wireless communications for the transfer of data to and from the computing device 1300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1306 may implement any of a number of wireless standards or protocols, including but not limited to Wi-Fi (IEEE 802.11 family), 3GPP, IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1300 may include a plurality of communication chips 1306. For instance, a first communication chip 1306 may be dedicated to shorter range wireless communications such as Wi-Fi and Bluetooth and a second communication chip 1306 may be dedicated to longer range wireless communications such as GPS, EDGE, GPRS, CDMA, WiMAX, LTE, Ev-DO, and others.

The processor 1304 of the computing device 1300 includes an integrated circuit die packaged within the processor 1304. In some implementations of the invention, the integrated circuit die of the processor may be part of an electronic package that comprises a first substrate that is aligned to a second substrate using at least partially overlapping fiducial structures, in accordance with embodiments described herein. The term “processor” may refer to any device or portion of a device that processes electronic data from registers and/or memory to transform that electronic data into other electronic data that may be stored in registers and/or memory.

The communication chip 1306 also includes an integrated circuit die packaged within the communication chip 1306. In accordance with another implementation of the invention, the integrated circuit die of the communication chip may be part of an electronic package that comprises a first substrate that is aligned to a second substrate using at least partially overlapping fiducial structures, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package architecture, comprising: a first substrate; a first fiducial mark on a surface of the first substrate; a second substrate over the first substrate, wherein the second substrate comprises glass; and a second fiducial mark on the second substrate, wherein a footprint of the second fiducial mark at least partially overlaps a footprint of the first fiducial mark.

Example 2: the package architecture of Example 1, wherein the second fiducial mark is recessed into a surface of the second substrate that faces the first substrate.

Example 3: the package architecture of Example 1 or Example 2, wherein the first fiducial mark is recessed into a surface of the first substrate that faces the second substrate.

Example 4: the package architecture of Examples 1-3, wherein the first fiducial mark contacts the second fiducial mark.

Example 5: the package architecture of Examples 1-4, wherein the first fiducial mark is a first material and the second fiducial mark is a second material that is different than the first material.

Example 6: the package architecture of Examples 1-5, wherein the footprint of the first fiducial mark is larger than the footprint of the second fiducial mark.

Example 7: the package architecture of Examples 1-6, wherein the first fiducial mark is circular and wherein the second fiducial mark is circular.

Example 8: the package architecture of Example 7, wherein the first fiducial mark is a circular ring.

Example 9: the package architecture of Example 7, wherein the second fiducial mark is a circular ring.

Example 10: the package architecture of Example 7, wherein the first fiducial mark and the second fiducial mark are both circular rings.

Example 11: the package architecture of Examples 1-10, wherein at least one of the first fiducial mark and the second fiducial mark are cross-shaped.

Example 12: the package architecture of Examples 1-11, wherein the second substrate is an interposer, or wherein the second substrate is a bridge inserted in a cavity in the first substrate.

Example 13: the package architecture of Examples 1-12, wherein the package substrate is coupled to a processor of a computing system.

Example 14: an interposer, comprising: a substrate, wherein the substrate comprises glass; a first fiducial mark embedded in a first recess into a first surface of the substrate, wherein the first fiducial mark is proximate a first corner of the substrate; and a second fiducial mark embedded in a second recess into the first surface of the substrate, wherein the second fiducial mark is proximate a second corner of the substrate, wherein the first corner is opposite from the second corner.

Example 15: the interposer of Example 14, wherein the glass is a borosilicate glass or a fused silica glass.

Example 16: the interposer of Example 14 or Example 15, wherein the first fiducial mark and the second fiducial mark are both circular.

Example 17: the interposer of Example 16, wherein the first fiducial mark and the second fiducial mark are both circular rings.

Example 18: the interposer of Examples 14-17, wherein the interposer is a bridge in a package substrate.

Example 19: the interposer of Examples 14-18, wherein the first fiducial mark is substantially similar to the second fiducial mark.

Example 20: the interposer of Examples 14-19, wherein the first fiducial mark and the second fiducial mark both comprise copper.

Example 21: the interposer of Examples 14-20, wherein surfaces of the first fiducial mark and the second fiducial mark are substantially coplanar with the first surface of the substrate.

Example 22: an electronic system, comprising: a board; a package substrate coupled to the board, wherein the package substrate comprises a first fiducial mark; an interposer coupled to the package substrate, wherein the interposer comprises glass and a second fiducial mark, and wherein the second fiducial mark at least partially overlaps the first fiducial mark; and a die coupled to the interposer.

Example 23: the electronic system of Example 22, wherein the first fiducial mark and the second fiducial mark are circular.

Example 24: the electronic system of Example 22 or Example 23, wherein at least one of the first fiducial mark and the second fiducial mark is cross-shaped.

Example 25: the electronic system of Examples 22-24, wherein the first fiducial mark is a first material and the second fiducial mark is a second material that is different than the first material.

What is claimed is:

1. A package architecture, comprising:
a first substrate;
a first fiducial mark on a surface of the first substrate;
a second substrate over the first substrate, wherein the second substrate comprises glass; and
a second fiducial mark on the second substrate, wherein a footprint of the second fiducial mark at least partially overlaps a footprint of the first fiducial mark.

2. The package architecture of claim 1, wherein the second fiducial mark is recessed into a surface of the second substrate that faces the first substrate.

3. The package architecture of claim 1, wherein the first fiducial mark is recessed into a surface of the first substrate that faces the second substrate.

4. The package architecture of claim 1, wherein the first fiducial mark contacts the second fiducial mark.

5. The package architecture of claim 1, wherein the first fiducial mark is a first material and the second fiducial mark is a second material that is different than the first material.

6. The package architecture of claim 1, wherein the footprint of the first fiducial mark is larger than the footprint of the second fiducial mark.

7. The package architecture of claim 1, wherein the first fiducial mark is circular and wherein the second fiducial mark is circular.

8. The package architecture of claim 7, wherein the first fiducial mark is a circular ring.

9. The package architecture of claim 7, wherein the second fiducial mark is a circular ring.

10. The package architecture of claim 7, wherein the first fiducial mark and the second fiducial mark are both circular rings.

11. The package architecture of claim 1, wherein at least one of the first fiducial mark and the second fiducial mark are cross-shaped.

12. The package architecture of claim 1, wherein the second substrate is an interposer, or wherein the second substrate is a bridge inserted in a cavity in the first substrate.

13. The package architecture of claim 1, wherein the package architecture is coupled to a processor of a computing system.

14. An interposer, comprising:
a substrate, wherein the substrate comprises glass;
a first fiducial mark embedded in a first recess into a first surface of the substrate, wherein the first fiducial mark is proximate a first corner of the substrate; and
a second fiducial mark embedded in a second recess into the first surface of the substrate, wherein the second fiducial mark is proximate a second corner of the substrate, wherein the first corner is opposite from the second corner.

15. The interposer of claim 14, wherein the glass is a borosilicate glass or a fused silica glass.

16. The interposer of claim 14, wherein the first fiducial mark and the second fiducial mark are both circular.

17. The interposer of claim 16, wherein the first fiducial mark and the second fiducial mark are both circular rings.

18. The interposer of claim 14, wherein the interposer is a bridge in a package substrate.

19. The interposer of claim 14, wherein the first fiducial mark is substantially similar to the second fiducial mark.

20. The interposer of claim 14, wherein the first fiducial mark and the second fiducial mark both comprise copper.

21. The interposer of claim 14, wherein surfaces of the first fiducial mark and the second fiducial mark are substantially coplanar with the first surface of the substrate.

22. An electronic system, comprising:
a board;
a package substrate coupled to the board, wherein the package substrate comprises a first fiducial mark;
an interposer coupled to the package substrate, wherein the interposer comprises glass and a second fiducial mark, and wherein the second fiducial mark at least partially overlaps the first fiducial mark; and
a die coupled to the interposer.

23. The electronic system of claim 22, wherein the first fiducial mark and the second fiducial mark are circular.

24. The electronic system of claim 22, wherein at least one of the first fiducial mark and the second fiducial mark is cross-shaped.

25. The electronic system of claim 22, wherein the first fiducial mark is a first material and the second fiducial mark is a second material that is different than the first material.
